(19) United States
(12) Patent Application Publication
(10) Pub. No.: US 2026/0299424 A1
(43) Pub. Date: Oct. 1, 2026

(54) SEMICONDUCTOR METHOD OF MANUFACTURE AND LAYER COMPOSITION

(71) Applicant: Taiwan Semiconductor Manufacturing Company Limited, Hsin-Chu (TW)

(72) Inventors: Yen-Hao CHEN, New Taipei City (TW); Wei-Han LAI, New Taipei City (TW); Kuan-Hsin LO, Nantou County (TW); Yahru CHENG, Taipei (TW)

(21) Appl. No.: 19/097,167

(22) Filed: Apr. 1, 2025

(51) Int. Cl. G03F 7/20; G03F 7/004; G03F 7/09; G03F 7/11; H01L 21/311

(52) U.S. Cl. CPC G03F 7/2041; G03F 7/0043; G03F 7/094; G03F 7/11; H10P 50/73

(57) ABSTRACT

A method for forming a semiconductor device and a photoresist protection layer composition are provided. The method includes forming a process layer. A metallic type photoresist layer is formed over the process layer. A photoresist protection layer is formed over the metallic type photoresist layer. The metallic type photoresist layer is exposed using patterned radiation in the presence of an immersion fluid in contact with the photoresist protection layer. A developing process is performed to remove the photoresist protection layer and to define a photoresist pattern based on the patterned radiation in the metallic type photoresist layer. The process layer is processed using the photoresist pattern as a template.

### BACKGROUND

As consumer devices have gotten smaller in response to consumer demand, the individual components of these devices have necessarily decreased in size as well. Semiconductor devices, which make up a major component of devices such as mobile phones, computer tablets, and the like, have been pressured to become smaller, with a corresponding pressure on the individual devices (e.g., transistors, resistors, capacitors, etc.) within the semiconductor devices to also be reduced in size. Immersion photolithography is an advancement in photolithography, in which the exposure procedure is performed with an immersion fluid filling the space between the surface of the wafer and the reticle. Using immersion photolithography, higher numerical apertures can be built than when using lenses in air, resulting in improved resolution. Further, immersion photolithography provides enhanced depth-of-focus (DOF) for printing ever smaller features.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1F are illustrations of a semiconductor device at various stages of fabrication, in accordance with some embodiments.

FIG. 2 is a diagram illustrating a polymer structure of a photoresist protection layer, in accordance with some embodiments.

FIGS. 3A-3F illustrate example polymer structures of a photoresist protection layer, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly

An enabling technology used in the manufacturing processes of semiconductor devices is photolithography processing for patterning process layers of devices to form structures therefrom. A photolithographic layer is applied to a surface and then exposed to an energy that has itself been patterned, for example by the use of radiation energy passing through a patterned reticle. Such an exposure modifies the chemical and physical properties of the exposed regions of the photolithographic layer. This modification, along with the lack of modification in regions of the photolithographic layer that were not exposed, can be exploited to remove one region without removing the other. The patterned photolithographic layer may be used as a template for further processing of the underlying process layer, such as etching the process layer or implanting dopants into the process layer. An immersion photolithography process using argon and fluorine (i-ArF) employs a radiation source at a wavelength of 193 nm. Due to pitch tightening and critical dimension (CD) shrink, the thickness of the photoresist layer is reduced to avoid the peeling effect for i-ArF 193 nm exposure.

One or more techniques for fabricating a semiconductor device are provided herein. According to some embodiments, to increase the etch budget, a metallic type photoresist material, such as a metal oxide photoresist material, is used for patterning the process layer of the semiconductor device. A photoresist protection layer is formed over the metallic type photoresist material to prevent reaction between the metallic type photoresist material and the immersion fluid resulting in metal leaching that could potentially affect the photolithography tool, such as by damaging the lens. In some embodiments, the photoresist protection layer is a waterproof or hydrophobic layer in applications where the immersion fluid is water.

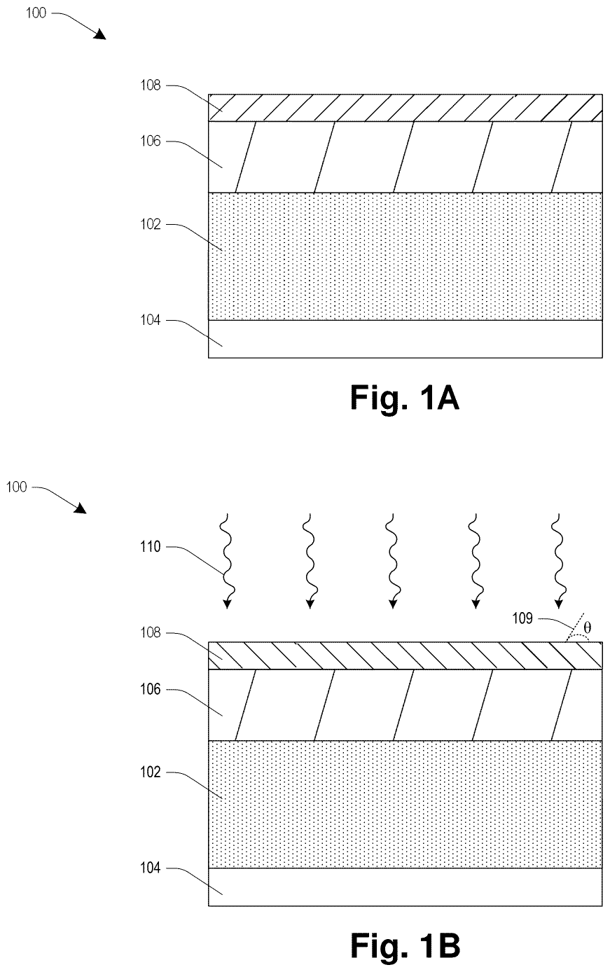

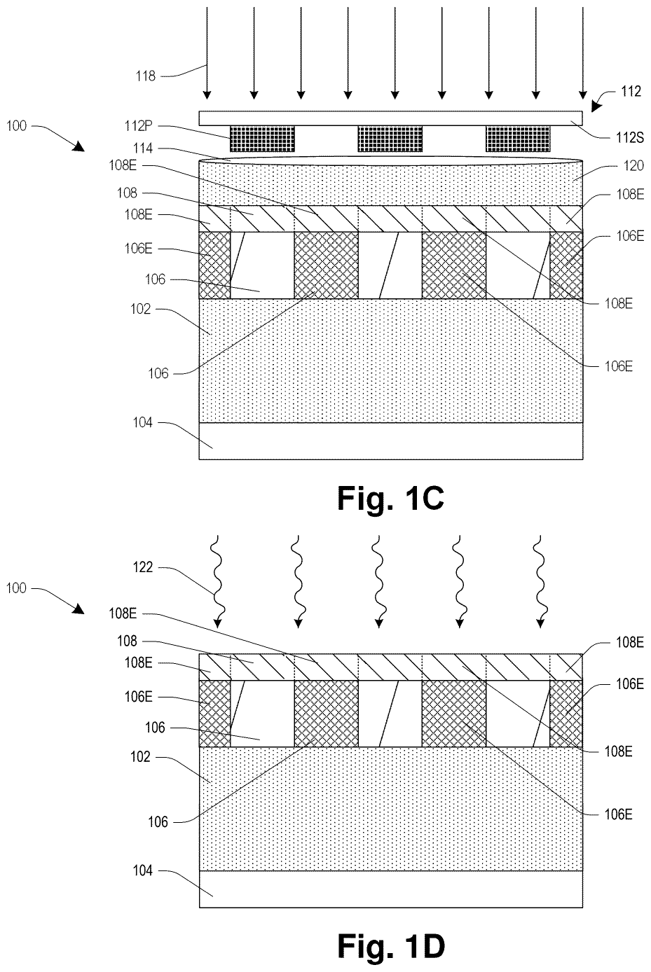

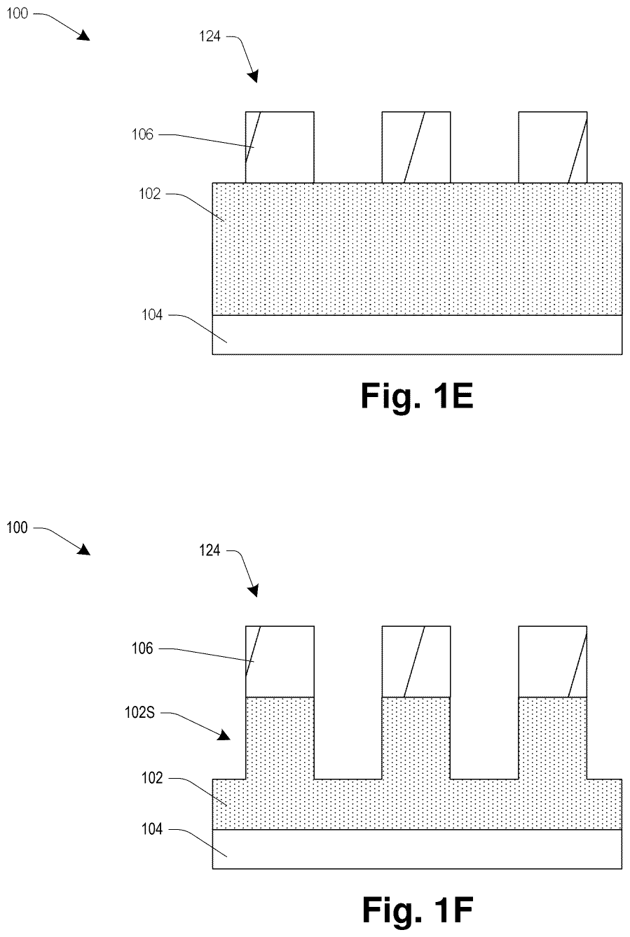

FIGS. 1A-1F are illustrations of a semiconductor device 100 at various stages of fabrication, in accordance with some embodiments. Referring to FIG. 1A, the semiconductor device 100 includes a process layer 102 formed over a substrate 104. In some embodiments, the process layer 102 is an upper portion of the substrate 104. In some embodiments, a metallic type photoresist layer 106 is formed over the process layer 102, and a photoresist protection layer 108 is formed over the metallic type photoresist layer 106. The photoresist protection layer 108 covers the metallic type photoresist layer 106 during an immersion photolithography process to reduce metal leaching from the metallic type photoresist layer 106 that could damage the photolithography tool. The photoresist protection layer 108 may be an organic polymer photoresist material or an inorganic photoresist material.

In some embodiments, the substrate 104 includes at least one of an epitaxial layer, a single crystalline semiconductor material such as, but not limited to Si, Ge, SiGe, InGaAs, GaAs, InSb, GaP, GaSb, InAlAs, GaSbP, GaAsSb, and InP, a silicon-on-insulator (SOI) structure, crystalline silicon, a semiconductor wafer, or a die formed from a semiconductor wafer. In some embodiments, the substrate 104 includes at least one metal, metal alloy, or metal/nitride/sulfide/oxide/silicide having the formula MXₐ, where M is a metal, X is nitrogen (N), sulfur (S), selenium (Se), oxygen (O), silicon (Si), and a is from about 0.4 to about 2.5. In some embodiments, the substrate 104 includes titanium, aluminum, cobalt, ruthenium, titanium nitride, tungsten nitride, tantalum nitride, or combinations thereof. In some embodiments, the substrate 104 includes a dielectric layer having at least silicon, metal oxide, and metal nitride of the formula MX_{b}, where M is a metal or Si, X is N or O, and b ranges from about 0.4 to about 2.5. Titanium (Ti), aluminum (Al), hafnium (Hf), zirconium (Zr), and lanthanum (La) are suitable metals for M in some embodiments. In some embodiments, the substrate 104 includes silicon dioxide, silicon nitride, aluminum oxide, hafnium oxide, lanthanum oxide, or combinations thereof.

In some embodiments, the metallic type photoresist layer 106 is a photosensitive layer that is patterned by exposure to actinic radiation and development. The chemical properties of the regions of the metallic type photoresist layer 106 struck by incident radiation change in a manner that depends on the type of photoresist used. The metallic type photoresist layer 106 may be a positive tone resist or a negative tone resist. A positive tone resist refers to a photoresist material that when exposed to radiation, such as ultraviolet (UV) light, becomes soluble in a developer, while the region of the photoresist material that is non-exposed (or exposed less) is insoluble in the developer. A negative tone resist, on the other hand, refers to a photoresist material that when exposed to radiation becomes insoluble in the developer, while the region of the photoresist material that is non-exposed (or exposed less) is soluble in the developer. The region of a negative resist that becomes insoluble upon exposure to radiation may become insoluble due to a cross-linking reaction caused by the exposure to radiation.

Whether a resist material is a positive tone or negative tone may depend on the type of developer used to develop the resist. For example, some positive tone photoresists provide a positive pattern (i.e., the exposed regions are removed by the developer) when the developer is an aqueous-based developer, such as a tetramethylammonium hydroxide (TMAH) solution. On the other hand, the same photoresist material provides a negative pattern (i.e., the unexposed regions are removed by the developer) when the developer is an organic solvent. Further, in some negative tone photoresists developed with a TMAH solution, the unexposed regions of the photoresist are removed by the TMAH, and the exposed regions of the photoresist, that undergo cross-linking upon exposure to actinic radiation, remain on the substrate after development.

In some embodiments, the metallic type photoresist layer 106 includes one or more metals, such as silver (Ag), cadmium (Cd), indium (Id), tin (Sn), antimony (Sb), tellurium (Te), cesium (Cs), gold (Au), mercury (Hg), thallium (Tl), lead (Pb), bismuth (Bi), polonium (Po), astatine (At), or other suitable metal. In some embodiments, the metallic type photoresist layer 106 is deposited as a liquid mixture, and the substrate 104 is rotated while the metallic type photoresist layer 106 is deposited over the substrate 104.

In some embodiments, the metallic type photoresist layer 106 includes metal oxide nanoparticles. The metal oxide nanoparticles are selected from the group including titanium dioxide, zinc oxide, zirconium dioxide, nickel oxide, cobalt oxide, manganese oxide, copper oxides, iron oxides, strontium titanate, tungsten oxides, vanadium oxides, chromium oxides, tin oxides, hafnium oxide, indium oxide, cadmium oxide, molybdenum oxide, tantalum oxides, niobium oxide, aluminum oxide, and combinations thereof in some embodiments. As used herein, nanoparticles are particles having an average particle size between 1 and 10 nm. In some embodiments, the metal oxide nanoparticles have an average particle size between 2 and 5 nm. In some embodiments, the amount of metal oxide nanoparticles in the metallic type photoresist layer 106 ranges from about 1 wt. % (weight percent) to about 10 wt. % based on the total weight of the metallic type photoresist layer 106.

In some embodiments, the metal oxide nanoparticles are complexed with carboxylic acid or sulfonic acid ligands. For example, in some embodiments, zirconium oxide or hafnium oxide nanoparticles are complexed with methacrylic acid forming hafnium methacrylic acid (HfMAA) or zirconium methacrylic acid (ZrMAA). In some embodiments, the HfMAA or ZrMAA are dissolved at about a 5 wt. % to about 10 wt. % weight range in a coating solvent, such as propylene glycol methyl ether acetate (PGMEA). In some embodiments, the metallic type photoresist layer 106 includes about 1 wt. % to about 10 wt. % of a photoactive compound (PAC) based on the total weight of the metallic type photoresist layer 106 to form a metal oxide resist.

The metallic type photoresist layer 106 may be a polymer along with one or more photoactive compounds (PACs) in a solvent, in some embodiments. In some embodiments, the polymer includes a hydrocarbon structure (such as an alicyclic hydrocarbon structure) that contains one or more groups that will decompose (e.g., acid labile groups (ALGs)) or otherwise react when mixed with acids, bases, or free radicals generated by the PACs (as further described below). In some embodiments, the hydrocarbon structure includes a repeating unit that forms a skeletal backbone of the polymer. This repeating unit may include acrylic esters, methacrylic esters, crotonic esters, vinyl esters, maleic diesters, fumaric diesters, itaconic diesters, (meth)acrylonitrile, (meth)acrylamides, styrenes, vinyl ethers, combinations of these, or the like.

The individual components of the metallic type photoresist layer 106 are placed into a solvent in order to aid in the mixing and dispensing of the photoresist. To aid in the mixing and dispensing of the photoresist, the solvent is chosen at least in part based upon the materials chosen for the polymers as well as the PAC. In some embodiments, the solvent is chosen such that the polymers and the PAC can be evenly dissolved into the solvent and dispensed upon the layer to be patterned. In some embodiments, the solvent is an organic solvent, and includes one or more of any suitable solvent such as ketones, alcohols, polyalcohols, ethers, glycol ethers, cyclic ethers, aromatic hydrocarbons, esters, propionates, lactates, lactic esters, alkylene glycol monoalkyl ethers, alkyl lactates, alkyl alkoxypropionates, cyclic lactones, monoketone compounds that contain a ring, alkylene carbonates, alkyl alkoxyacetate, alkyl pyruvates, lactate esters, ethylene glycol alkyl ether acetates, diethylene glycols, propylene glycol alkyl ether acetates, alkylene glycol alkyl ether esters, alkylene glycol monoalkyl esters, or the like.

The metallic type photoresist layer 106 may be formed using spin-on techniques or sputtering techniques, such as physical vapor deposition (PVD). In an embodiment where the metallic type photoresist layer 106 is an organic polymer, a spin-dry process or heating process may be performed after applying the materials of the metallic type photoresist layer 106 and prior to forming the photoresist protection layer 108 to remove solvent from the metallic type photoresist layer 106. In an embodiment where the metallic type photoresist layer 106 is an inorganic material, the spin-dry process or heating process may be omitted.

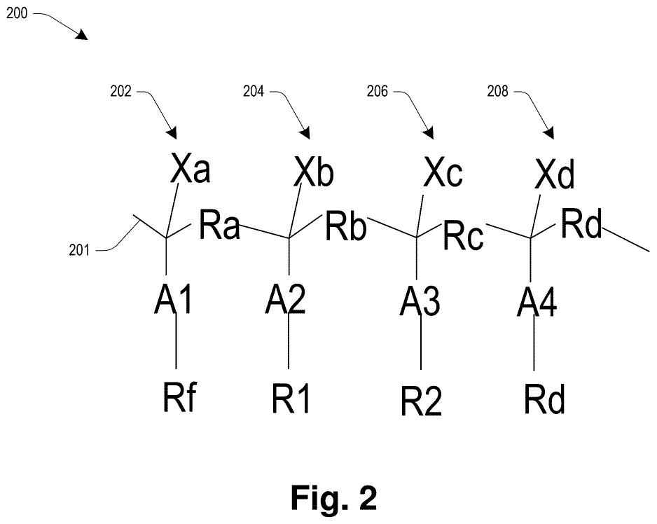

The photoresist protection layer 108 may be formed using spin-on techniques. FIG. 2 is a diagram illustrating a polymer 200 of the photoresist protection layer 108, in accordance with some embodiments. In some embodiments, the polymer 200 includes a backbone 201 connected to a floating group 202, an acid diffusion group 204 having a high glass transition temperature (Tg) (e.g., about 120° C.-200° C.), a solubility promotor group 206 for promoting wet developer solubility, and an optional dye group 208.

In some embodiments, the backbone 201 is a hydrocarbon structure, such as an alicyclic hydrocarbon structure, that includes a repeating unit that forms a skeletal backbone of the polymer. This repeating unit may include acrylic esters, methacrylic esters, crotonic esters, vinyl esters, maleic diesters, fumaric diesters, itaconic diesters, (meth)acrylonitrile, (meth)acrylamides, styrenes, vinyl ethers, combinations of these, or other suitable structures.

In some embodiments, the repeating unit of the hydrocarbon structure also has either a monocyclic or a polycyclic hydrocarbon structure substituted into it, or the monocyclic or polycyclic hydrocarbon structure is the repeating unit, in order to form an alicyclic hydrocarbon structure. Specific examples of monocyclic structures in some embodiments include bicycloalkane, tricycloalkane, tetracycloalkane, cyclopentane, cyclohexane, or the like. Specific examples of polycyclic structures in some embodiments include adamantane, norbornane, isobornane, tricyclodecane, or tetracyclododecane.

In some embodiments, the floating group 202 includes a fluorine (Rf) unit that reduces the surface energy to promote distribution of the floating group 202 near a top surface of the polymer to provide a hydrophobic top surface during spin dry or post coating bake. The Rf unit may include a C1-C9 fluoro-alcohol unit to promote wet developer solubility (e.g., in a wet developer such as tetramethylammonium hydroxide (TMAH)).

In some embodiments, the acid diffusion group 204 includes an R1 unit, such as a C5-C20 alkyl group, cycloalkyl group, hydroxylalkyl group, alkoxy group, alkoxyl alkyl group, bulkyl group, acetyl group, acetylalkyl group, carboxyl group, alky carboxyl group, cycloalkyl carboxyl group, C5-C20 saturated or unsaturated hydrocarbon ring, or C5-C20 heterocyclic group which can be a 2-D ring, a 3-D crisscross structure, or other rigid group that exhibits a high Tg to control the profile of the photoresist protection layer 108 and also provide a hydrophobic characteristic to the photoresist protection layer 108.

In some embodiments, the solubility promotor group 206 includes an R2 unit having a ring structure that promotes wet or dry developer solubility by undergoing a ring-opening reaction in the presence of the wet developer (e.g., a solution having a pH value>10, TMAH, or some other developer) to change to carboxylic acid and dissolve. The R2 unit may be butyrolactone, an acid, a thermal acid generator, or a photo acid generator. In some embodiments, the dye group 208 includes an Rd unit, such as benzene, naphthalene, or phenanthrene and pentacenequinone derivatives that may absorb out of band (OOB) radiation (e.g., 100-400 nm radiation) and improve photolithography performance, for example, by absorbing waste radiation having wavelengths other than the wavelength (e.g., 193 nm for i-ArF) used for exposure.

Referring to FIG. 2, the backbone 201 includes Xa, Xb, Xc, Xd units, such as independent H, methyl, or fluorine units; A1, A2, A3, A4 units, such as independent polycarboxylates (COO—) or phenols (PhO—); and R1, R2, R3, R4 units, such as independent C0-C7 alkyl groups, aromatic groups, or other suitable groups.

In some embodiments, the concentration of the floating group 202 (m) by weight percent is about 0.2<m<0.8, the concentration of the acid diffusion group 204 (n) by weight percent is about 0.2<n<0.8, the concentration of the solubility promotor group 206 (o) by weight percent is about 0<=o<0.5, and the concentration of the dye group 208 (p) by weight percent is about 0<=p<0.5 , where the sum of the concentrations m+n+o+p=1.

In some embodiments, the individual components of the polymer 200 of the photoresist protection layer 108 are placed into a solvent to aid in the mixing and dispensing of the photoresist protection layer 108. To aid in the mixing and dispensing, the solvent is chosen at least in part based upon the materials chosen for the polymer 200. In some embodiments, the solvent is an organic solvent, and includes one or more of any suitable solvent such as ketones, alcohols, polyalcohols, ethers, glycol ethers, cyclic ethers, aromatic hydrocarbons, esters, propionates, lactates, lactic esters, alkylene glycol monoalkyl ethers, alkyl lactates, alkyl alkoxypropionates, cyclic lactones, monoketone compounds that contain a ring, alkylene carbonates, alkyl alkoxyacetate, alkyl pyruvates, lactate esters, ethylene glycol alkyl ether acetates, diethylene glycols, propylene glycol alkyl ether acetates, alkylene glycol alkyl ether esters, alkylene glycol monoalkyl esters, or the like.

Specific examples of materials that may be used as the solvent for the photoresist protection layer composition include acetone, methanol, ethanol, propanol, isopropanol (IPA), n-butanol, toluene, xylene, 4-hydroxy-4-methyl-2-pentatone, tetrahydrofuran (THF), methyl ethyl ketone, cyclohexanone (CHN), methyl isoamyl ketone, 2-heptanone (MAK), ethylene glycol, 1-ethoxy-2-propanol, methyl isobutyl carbinol (MIBC), ethylene glycol monoacetate, ethylene glycol dimethyl ether, ethylene glycol dimethyl ether, ethylene glycol methylethyl ether, ethylene glycol monoethyl ether, methyl cellosolve acetate, ethyl cellosolve acetate, diethylene glycol, diethylene glycol monoacetate, diethylene glycol monomethyl ether, diethylene glycol diethyl ether, diethylene glycol dimethyl ether, diethylene glycol ethylmethyl ether, diethethylene glycol monoethyl ether, diethylene glycol monobutyl ether, ethyl 2-hydroxypropionate, methyl 2-hydroxy-2-methylpropionate, ethyl 2-hydroxy-2-methylpropionate, ethyl ethoxyacetate, ethyl hydroxyacetate, methyl 2-hydroxy-2-methylbutanate, methyl 3-methoxypropionate, ethyl 3-methoxypropionate, methyl 3-ethoxypropionate, ethyl 3-ethoxypropionate, methyl acetate, ethyl acetate, propyl acetate, n-butyl acetate (nBA), methyl lactate, ethyl lactate (EL), propyl lactate, butyl lactate, propylene glycol, propylene glycol monoacetate, propylene glycol monoethyl ether acetate, propylene glycol monomethyl ether acetate, propylene glycol monopropyl methyl ether acetate, propylene glycol monobutyl ether acetate, propylene glycol monobutyl ether acetate, propylene glycol monomethyl ether propionate, propylene glycol monoethyl ether propionate, propylene glycol methyl ether acetate, propylene glycol ethyl ether acetate, ethylene glycol monomethyl ether acetate, ethylene glycol monoethyl ether acetate, propylene glycol monomethyl ether, propylene glycol monoethyl ether, propylene glycol monopropyl ether, propylene glycol monobutyl ether, ethylene glycol monomethyl ether, ethylene glycol monoethyl ether, ethyl 3-ethoxypropionate, methyl 3-methoxypropionate, methyl 3-ethoxypropionate, and ethyl 3-methoxypropionate, β-propiolactone, β-butyrolactone, γ-butyrolactone (GBL), α-methyl-γ-butyrolactone, β-methyl-γ-butyrolactone, γ-valerolactone, γ-caprolactone, γ-octanoic lactone, α-hydroxy-γ-butyrolactone, 2-butanone, 3-methylbutanone, pinacolone, 2-pentanone, 3-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexene-2-one, 3-pentene-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, 3-methylcycloheptanone, propylene carbonate, vinylene carbonate, ethylene carbonate, butylene carbonate, acetate-2-methoxyethyl, acetate-2-ethoxyethyl, acetate-2-(2-ethoxyethoxy)ethyl, acetate-3-methoxy-3-methylbutyl, acetate-1-methoxy-2-propyl, dipropylene glycol, monomethylether, monoethylether, monopropylether, monobutylether, monophenylether, dipropylene glycol monoacetate, dioxane, methyl pyruvate, ethyl pyruvate, propyl pyruvate, methyl methoxypropionate, ethyl ethoxypropionate, n-methylpyrrolidone (NMP), 2-methoxyethyl ether (diglyme), ethylene glycol monomethyl ether, propylene glycol monomethyl ether, methyl propionate, ethyl propionate, ethyl ethoxy propionate, methylethyl ketone, cyclohexanone, 2-heptanone, cyclopentanone, cyclohexanone, ethyl 3-ethoxypropionate, propylene glycol methyl ether acetate (PGMEA), methylene cellosolve, 2-ethoxyethanol, N-methylformamide, N,N-dimethylformamide (DMF), N-methylformanilide, N-methylacetamide, N,N-dimethylacetamide, dimethylsulfoxide, benzyl ethyl ether, dihexyl ether, acetonylacetone, isophorone, caproic acid, caprylic acid, 1-octanol, 1-nonanol, benzyl alcohol, benzyl acetate, ethyl benzoate, diethyl oxalate, diethyl maleate, phenyl cellosolve acetate, or the like.

The materials listed and described above as examples of materials that may be used for the solvent of the photoresist protection layer 108 are merely illustrative and are not intended to limit the embodiments. Rather, any suitable materials that dissolve the polymers may be used to help mix and apply the photoresist protection layer 108.

Although the example solvents provided for the metallic type photoresist layer 106 and the photoresist protection layer 108 may overlap, the particular polymers for the metallic type photoresist layer 106 and the photoresist protection layer 108 are selected so that the solvents are different to provide that the solvent for the photoresist protection layer 108 does not dissolve the metallic type photoresist layer 106.

Referring to FIG. 1B, a solidification process 110 is performed after applying the materials of the photoresist protection layer 108, in accordance with some embodiments. The solidification process may be a spin-dry process or a heating process that removes solvent from the photoresist protection layer 108. After the solidification process, the photoresist protection layer 108 exhibits a surface contact angle 109 (θ) of at least 50° to provide a hydrophobic surface. In some embodiments, the solidification process includes heating of the photoresist protection layer 108. In some embodiments, the floating group 202 promotes the hydrophobic surface of the photoresist protection layer 108.

Referring to FIG. 1C, an exposure process is performed to form exposed portions 106E of the metallic type photoresist layer 106, in accordance with some embodiments. In some embodiments, where the polymer 200 of the exposed portions 108E of the photoresist protection layer 108 includes PACs, the exposure process also forms exposed portions 108E of the photoresist protection layer 108, which are represented by dashed lines since this optional. In some embodiments, the exposure process is performed in a photolithography tool that includes a photomask 112, optics 114 (e.g., a lens), an exposure radiation source (not shown) to provide radiation 118 for exposure, and a movable stage (not shown) for supporting and moving the substrate 104 under the radiation 118. The radiation 118 passes through the photomask 112 and becomes patterned radiation. In some embodiments, the exposure radiation source is an ArF excimer laser producing light having a wavelength of 193 nm. An immersion lithography technique is employed where an immersion fluid 120 is provided between the optics 114 and the semiconductor device 100 such that the radiation 118 passes through the immersion fluid 120. The photoresist protection layer 108 prevents the immersion fluid 120 from contacting the metallic type photoresist layer 106, avoiding metal leeching that could damage the optics 114. In some embodiments, the exposure radiation 118 induces a reaction of the PACs in the metallic type photoresist layer 106, which in turn reacts with compounds, such as photo-active groups (PAGs), in the metallic type photoresist layer 106 to chemically alter those portions 106E of the metallic type photoresist layer 106 to which the radiation 118 impinges.

As shown in FIG. 1C, the radiation 118 passes through the photomask 112 before irradiating the metallic type photoresist layer 106. In some embodiments, the photomask 112 defines a pattern to be replicated in the metallic type photoresist layer 106. The pattern is formed by an opaque pattern 112P on the photomask 112, in some embodiments. The opaque pattern 112P may be formed by a material opaque to the radiation 118, such as chromium, while a substrate 112S of the photomask 112 is formed of a material that is transparent to the radiation 118, such as fused quartz.

In some embodiments, the metallic type photoresist layer 106 includes a PAC, such as a PAG, that induces decomposition of an ALG pendant to the hydrocarbon main chain structure or backbone of the polymer forming the metallic type photoresist layer 106. In some embodiments, a cross linking agent is used. The radiation 118 impinges upon the PAG, and the PAG absorbs the impinging radiation 118. This absorption initiates the PAG to generate a proton (e.g., an H+ atom) within the metallic type photoresist layer 106. When the proton impacts the ALG on the hydrocarbon structure, the proton reacts with the ALG, chemically altering the ALG and altering the properties of the polymer in general. The acid generated by the PAG cleaves the ALG on the polymer with the pendant ALG, thereby increasing the solubility of the polymer in the developer.

In some embodiments, the polymer 200 of the photoresist protection layer 108 includes a PAG (such as R2) that absorbs the impinging radiation 118 and generates a proton (e.g., an H+ atom) within the photoresist protection layer 108 that reacts with an ALG in the polymer 200 and cleaves the ALG on the polymer 200, thereby increasing the solubility of the polymer 200 in the developer.

Referring to FIG. 1D, a heating process 122 is performed on the metallic type photoresist layer 106 and the photoresist protection layer 108, in accordance with some embodiments. In some embodiments, the heating process 122 is a post-exposure baking (PEB) process. The heating process 122 may be performed at a temperature of about 80° C. to about 300° C. for about 10 seconds to about 10 minutes. During the heating process 122, additional acid is generated in the exposed portions 106E of the metallic type photoresist layer 106 (i.e., and the exposed portions of the photoresist protection layer 108 if the polymer 200 includes a PAG) to further the chemical changes in the metallic type photoresist layer 106 and optionally the photoresist protection layer 108. In some embodiments, crosslinking occurs in the metallic type photoresist layer 106 during the heating process 122.

Referring to FIG. 1E a development process is performed to remove the photoresist protection layer 108 and the exposed portions 106E of the metallic type photoresist layer 106 to form a photoresist pattern 124, in accordance with some embodiments. In some embodiments, the development process includes applying a wet or dry solvent that removes the photoresist protection layer 108 and the exposed portions 106E of the metallic type photoresist layer 106. Although the example of FIG. 1E illustrates a positive tone development process where the exposed portions 106E of the metallic type photoresist layer 106 are removed, a negative tone development process may also be used, where the exposed portions 106E of the metallic type photoresist layer 106 remain after development.

In some embodiments, the development process may employ a dry development process using a plasma including argon or chlorine. Alternatively, a positive tone developer such as one or more of a basic aqueous solution, tetramethylammonium hydroxide (TMAH), tetrabutylammonium hydroxide, sodium hydroxide, potassium hydroxide, sodium carbonate, sodium bicarbonate, sodium silicate, sodium metasilicate, aqueous ammonia, monomethylamine, dimethylamine, trimethylamine, monoethylamine, diethylamine, triethylamine, monoisopropylamine, diisopropylamine, triisopropylamine, monobutylamine, dibutylamine, monoethanolamine, diethanolamine, triethanolamine, dimethylaminoethanol, diethylaminoethanol, ammonia, caustic soda, caustic potash, sodium metasilicate, potassium metasilicate, sodium carbonate, tetraethylammonium hydroxide, combinations of these, or other suitable material may be used.

Referring to FIG. 1F, the photoresist pattern 124 is transferred to the process layer 102 to define structures 102S in the process layer 102, in accordance with some embodiments. In some embodiments, the photoresist pattern 124 may be transferred to the process layer 102 by performing an etch process using the photoresist pattern 124 in the metallic type photoresist layer 106 as an etch template. The particular type of etch process may depend on the material of the process layer 102. After the etch process, remaining portions of the metallic type photoresist layer 106 are removed by a suitable removal operation, such as an Ar or Cl plasma process. The structures 102S may be fins, pillars, trenches, lines, or some other feature.

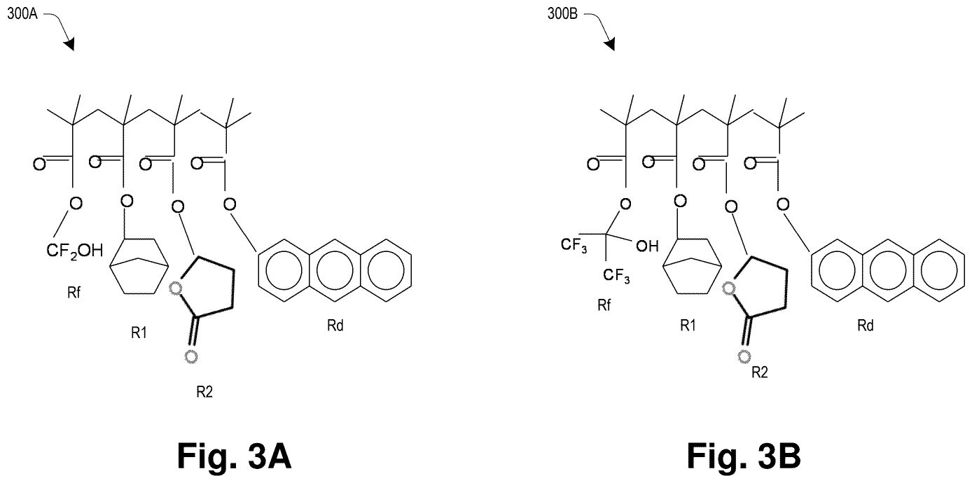

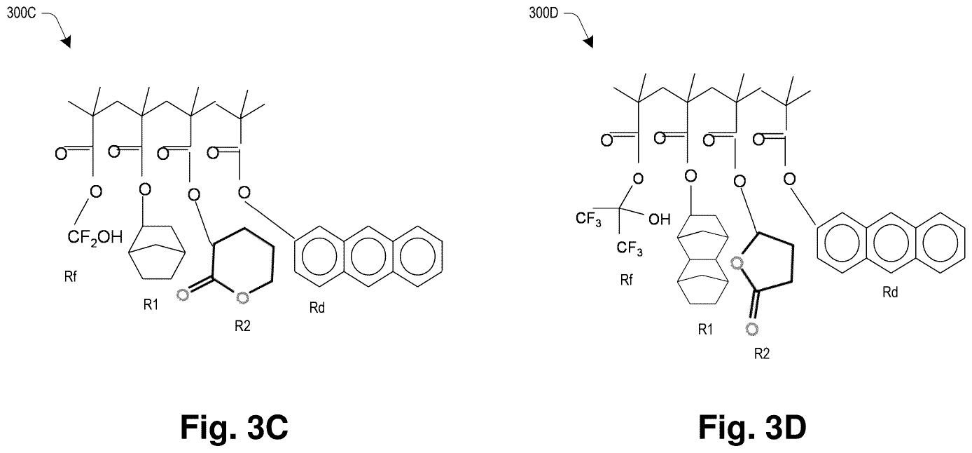

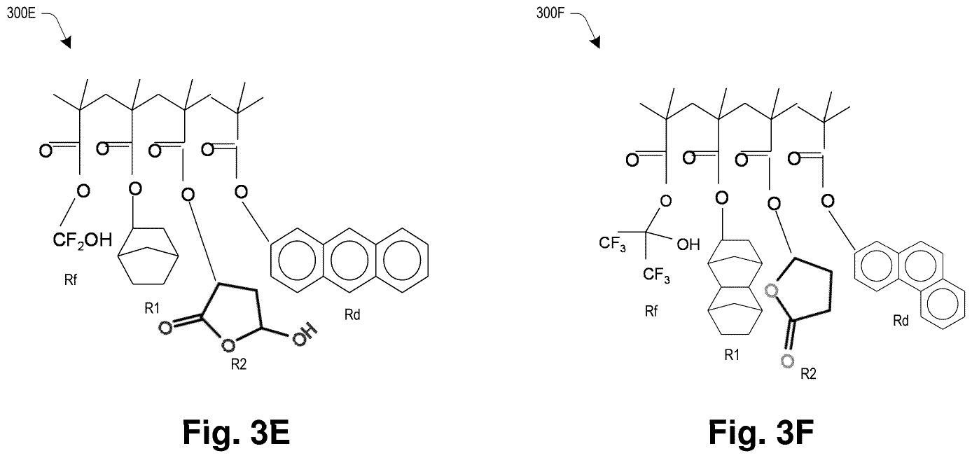

FIGS. 3A-3F illustrate example polymer structures of the photoresist protection layer 108, in accordance with some embodiments. In general, in the polymer structures of FIGS. 3A-3F, the Rf unit in the floating group 202 includes a fluoro-alcohol group, the R1 unit in the acid diffusion group 204 includes a bulkyl group, the R2 unit in the solubility promotor group 206 includes a butyrolactone group, and the Rd unit in the optional dye group 208 includes a benzene group.

In the polymer 300A illustrated in FIG. 3A, the Rf unit in the floating group 202 includes a fluoromethanol group, the R1 unit in the acid diffusion group 204 includes a bulkyl group, the R2 unit in the solubility promotor group 206 includes a gamma-butyrolactone group connected at ring position 1, and the Rd unit in the optional dye group 208 includes anthracene. In the polymer 300B illustrated in FIG. 3B, the Rf unit in the floating group 202 includes a fluoroethanol group, the R1 unit in the acid diffusion group 204 includes a bulkyl group, the R2 unit in the solubility promotor group 206 includes a gamma-butyrolactone group connected at ring position 1, and the Rd unit in the optional dye group 208 includes anthracene. In the polymer 300C illustrated in FIG. 3C, the Rf unit in the floating group 202 includes a fluoromethanol group, the R1 unit in the acid diffusion group 204 includes a bulkyl group, the R2 unit in the solubility promotor group 206 includes a gamma-butyrolactone group connected at ring position 4, and the Rd unit in the optional dye group 208 includes anthracene. In the polymer 300D illustrated in FIG. 3D, the Rf unit in the floating group 202 includes a fluoroethanol group, the R1 unit in the acid diffusion group 204 includes a two unit bulkyl group, the R2 unit in the solubility promotor group 206 includes a gamma-butyrolactone group connected at ring position 1, and the Rd unit in the optional dye group 208 includes anthracene. In the polymer 300E illustrated in FIG. 3E, the Rf unit in the floating group 202 includes a fluoromethanol group, the R1 unit in the acid diffusion group 204 includes a bulkyl group, the R2 unit in the solubility promotor group 206 includes a 1-hydroxy-gamma-butyrolactone group connected at ring position 4, and the Rd unit in the optional dye group 208 includes anthracene. In the polymer 300F illustrated in FIG. 3F, the Rf unit in the floating group 202 includes a fluoroethanol group, the R1 unit in the acid diffusion group 204 includes a bulkyl group, the R2 unit in the solubility promotor group 206 includes a gamma-butyrolactone group connected at ring position 1, and the Rd unit in the optional dye group 208 includes phenanthracene.

The photoresist protection layer 108 formed over the metallic type photoresist layer 106 prevents a reaction between the metallic type photoresist layer 106 and the immersion fluid 120 used during the exposure process that could result in metal leaching. This metal leaching could potentially affect the photolithography tool, such as by damaging the optics 114 (e.g., a lens). In an application where the immersion fluid 120 is water, the photoresist protection layer 108 may be a hydrophobic layer.

A method for forming the semiconductor device is provided. A process layer is formed. A metallic type photoresist layer is formed over the process layer. A photoresist protection layer is formed over the metallic type photoresist layer. The metallic type photoresist layer is exposed using patterned radiation in the presence of an immersion fluid in contact with the photoresist protection layer. A developing process is performed to remove the photoresist protection layer and to define a photoresist pattern based on the patterned radiation in the metallic type photoresist layer. The process layer is processed using the photoresist pattern as a template.

A method for forming a semiconductor device is provided and includes forming a process layer. A photoresist layer is formed over the process layer. A photoresist protection layer having a surface contact angle of at least 50° is formed over the photoresist layer. The photoresist layer is exposed using patterned radiation in the presence of an immersion fluid in contact with the photoresist protection layer to define exposed portions of the photoresist layer. A developing process is performed to remove one of the exposed portions of the photoresist layer or portions of the photoresist layer other than the exposed portions of the photoresist layer to define a photoresist pattern. The process layer is processed using the photoresist pattern as a template.

A photoresist protection layer composition includes a solvent, a floating group that distributes to a top surface of the photoresist protection layer composition in the solvent, an acid diffusion group, and a developer solubility promotor group.

The foregoing outlines features of several embodiments so that those of ordinary skill in the art may better understand various aspects of the present disclosure. Those of ordinary skill in the art should appreciate that they may readily use the present disclosure as a basis for designing or modifying other processes and structures for carrying out the same purposes and/or achieving the same advantages of various embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is

1. A method for forming a semiconductor device, comprising:
forming a process layer;
forming a metallic type photoresist layer over the process layer;
forming a photoresist protection layer over the metallic type photoresist layer;
exposing the metallic type photoresist layer using patterned radiation in the presence of an immersion fluid in contact with the photoresist protection layer;
performing a developing process to remove the photoresist protection layer and to define a photoresist pattern based on the patterned radiation in the metallic type photoresist layer; and
processing the process layer using the photoresist pattern as a template.

2. The method of claim 1, wherein:
the immersion fluid is water,
exposing the metallic type photoresist layer using the patterned radiation in the presence of the immersion fluid in contact with the photoresist protection layer comprises:
exposing the metallic type photoresist layer using the patterned radiation in the presence of the water in contact with the photoresist protection layer, and
the photoresist protection layer has a surface contact angle of at least 50°.

3. The method of claim 1, wherein:
the immersion fluid comprises water, and
forming the photoresist protection layer comprises forming a hydrophobic photoresist protection layer.

4. The method of claim 1, wherein forming the photoresist protection layer comprises:
forming a polymer composition comprising:
a solvent;
a floating group that distributes to a top surface of the polymer composition;
an acid diffusion group; and
a developer solubility promotor group; and
removing the solvent.

5. The method of claim 4, wherein:
forming the photoresist protection layer comprises forming the polymer composition comprising:
a dye group.

6. The method of claim 1, wherein:
forming the photoresist protection layer comprises forming a polymer comprising:
a fluoro-alcohol group;
a bulkyl group; and
a butyrolactone group.

7. The method of claim 1, wherein forming the photoresist protection layer comprises:
forming a polymer comprising a group comprising fluorine.

8. The method of claim 1, wherein forming the photoresist protection layer comprises:
forming a polymer comprising a ring structure that undergoes a ring-opening reaction during the developing process.

9. A method for forming a semiconductor device, comprising:
forming a process layer;
forming a photoresist layer over the process layer;
forming a photoresist protection layer having a surface contact angle of at least 50° over the photoresist layer;
exposing the photoresist layer using patterned radiation in the presence of an immersion fluid in contact with the photoresist protection layer to define exposed portions of the photoresist layer;
performing a developing process to remove one of the exposed portions of the photoresist layer or portions of the photoresist layer other than the exposed portions of the photoresist layer to define a photoresist pattern; and
processing the process layer using the photoresist pattern as a template.

10. The method of claim 9, wherein:
the immersion fluid is water, and
exposing the photoresist layer using the patterned radiation in the presence of the immersion fluid in contact with the photoresist protection layer comprises:
exposing the photoresist layer using the patterned radiation in the presence of the water in contact with the photoresist protection layer.

11. The method of claim 9, wherein:
the immersion fluid comprises water, and
forming a photoresist protection layer comprises forming a hydrophobic photoresist protection layer.

12. The method of claim 9, wherein forming the photoresist protection layer comprises:
forming a polymer composition comprising:
a solvent;
a floating group that distributes to a top surface of the polymer composition;
an acid diffusion group; and
a developer solubility promotor group; and
removing the solvent.

13. The method of claim 12, wherein:
forming the photoresist protection layer comprises forming the polymer composition comprising:
a dye group.

14. The method of claim 9, wherein:
forming the photoresist protection layer comprises forming a polymer comprising:
a fluoro-alcohol group;
a bulkyl group; and
a butyrolactone group.

15. The method of claim 9, wherein forming the photoresist protection layer comprises:
forming a polymer comprising a group comprising fluorine.

16. The method of claim 9, wherein forming the photoresist protection layer comprises:
forming a polymer comprising a ring structure that undergoes a ring-opening reaction during the developing process.

17. A photoresist protection layer composition, comprising:
a solvent;
a floating group that distributes to a top surface of the photoresist protection layer composition in the solvent;
an acid diffusion group; and
a developer solubility promotor group.

18. The photoresist protection layer composition of claim 17, comprising:
a dye group.

19. The photoresist protection layer composition of claim 17, wherein:
the floating group comprises fluorine,
the acid diffusion group comprises a bulkyl group, and
the developer solubility promotor group comprises a butyrolactone group.

20. The photoresist protection layer composition of claim 17, wherein:
the acid diffusion group comprises a ring structure.
